(19) United States
(12) Patent Application Publication
(10) Pub. No.: US 2020/0343329 A1
(43) Pub. Date: Oct. 29, 2020

(54) ARRAY SUBSTRATE, MANUFACTURING METHOD THEREFOR, AND DISPLAY DEVICE

(71) Applicants: Beijing BOE Display Technology Co., Ltd., Beijing (CN); BOE TECHNOLOGY GROUP CO., LTD., Beijing (CN)

(72) Inventors: Shoukun WANG, Beijing (CN); Xibin SHAO, Beijing (CN); Yongzhi SONG, Beijing (CN); Huibin GUO, Beijing (CN)

(21) Appl. No.: 16/758,488

(22) PCT Filed: Sep. 19, 2018
(86) PCT No.: PCT/CN2018/106546

§ 371 Date: Apr. 23, 2020

(30) Foreign Application Priority Data
Dec. 15, 2017 (CN) 201711351791.2

(51) Int. Cl. H01L 27/32; H01L 51/56

(52) U.S. Cl. CPC H01L 27/3276; H01L 2227/323; H01L 2251/303; H01L 51/56

(57) ABSTRACT

An array substrate includes a base substrate and a metal wiring layer located on the base substrate, where the metal wiring layer includes a first molybdenum oxide substrate layer and a first metal layer on the first molybdenum oxide substrate layer.

### CROSS REFERENCE TO RELATED APPLICATIONS

This application is based on International Application No. PCT/CN2018/106546 filed on Sep. 19, 2018, which is based upon, claims the benefit of, and claims priority to Chinese Patent Application No. 201711351791.2, filed Dec. 15, 2017, the entire contents of which are incorporated herein by reference.

### TECHNICAL FIELD

The present disclosure relates to the field of display technology, and more particularly, to an array substrate, manufacturing method therefor, and a display device.

### BACKGROUND

With the advancement of science and technology, more and more electronic devices, for example, terminal devices, such as smart phones, tablet computers, and LCD TVs, have entered people's lives and enriched and facilitated daily life.

A display panel is one of the important components for acquiring information in the electronic device. Furthermore, the performance of an array substrate determines the performance of the display panel, and its performance directly affects the performance of the terminal device and user experience. Metal traces are usually formed on a base substrate in the art. However, the reflectivity of the metal traces is extremely high and adhesion between metal and the substrate is limited, leading to a series of problems. These problems greatly limit the performance of the display panel and a display device.

In view of this, there is an urgent need to develop a high-performance array substrate, a display panel, and a display device, in order to reduce the reflectivity of metal wiring, and improve adhesion between the metal wiring and the base substrate so as to further improve the performance of the display panel and the display device.

It should be noted that information disclosed in the Background is provided only for acquiring a better understanding of the background of the present disclosure and therefore, may include information that is not current technology already known to those of ordinary skill in the art.

### SUMMARY

According to a first aspect of the present disclosure, there is provided an array substrate, comprising:

a base substrate; and

a metal wiring layer located on the base substrate, wherein the metal wiring layer comprises a first molybdenum oxide substrate layer and a first metal layer on a surface of the first molybdenum oxide substrate layer away from the base substrate.

In an exemplary embodiment of the present disclosure, the first molybdenum oxide substrate layer is a substrate layer directly formed by adopting a physical vapor deposition method.

In an exemplary embodiment of the present disclosure, the array substrate further comprises a thin film transistor provided on the base substrate, and a gate electrode of the thin film transistor comprises the metal wiring layer.

In an exemplary embodiment of the present disclosure, a source/drain electrode of the thin film transistor comprises a second molybdenum oxide layer and a second metal layer on a surface of the second molybdenum oxide substrate layer away from the base substrate.

In an exemplary embodiment of the present disclosure, the array substrate further comprises a trace pattern, and the trace pattern comprises the metal wiring layer.

In an exemplary embodiment of the present disclosure, the first molybdenum oxide substrate layer has a thickness not less than 50 Å.

In an exemplary embodiment of the present disclosure, the first metal layer is made of copper or aluminum.

In an exemplary embodiment of the present disclosure, the base substrate is a glass substrate.

According to a second aspect of the present disclosure, there is provided a method for manufacturing an array substrate, comprising:

forming a first molybdenum oxide substrate layer on a base substrate; and

forming a first metal layer on a surface of the first molybdenum oxide substrate layer away from the base substrate, wherein the first molybdenum oxide substrate layer and the first metal layer form a metal wiring layer.

In an exemplary embodiment of the present disclosure, the method for manufacturing an array substrate further comprises forming a thin film transistor on the base substrate, and

forming the thin film transistor on the base substrate comprises:

forming the pattern comprising the gate electrode of the thin film transistor by performing a patterning process on the metal wiring layer;

forming the gate insulating layer on the gate electrode;

forming an active layer thin film on the gate insulating layer, and forming a pattern comprising the active layer by a patterning process; and

forming a source/drain electrode material layer on the active layer, and forming a pattern comprising the source/drain electrode through a patterning process.

In an exemplary embodiment of the present disclosure, forming the source/drain electrode comprises: forming a second molybdenum oxide substrate layer on the active layer; forming a second metal layer on the second molybdenum oxide base layer; and forming the pattern comprising the source/drain electrode through a patterning process.

In an exemplary embodiment of the present disclosure, the method for manufacturing an array substrate further comprises forming a trace pattern on the metal wiring layer through a patterning process.

In an exemplary embodiment of the present disclosure, the first molybdenum oxide substrate layer is directly formed by adopting a physical vapor deposition method, with deposition parameters of argon flow rate of 10˜3000 sccm, an air pressure of 0.1-2 Pa, power of 0.5-80 kw, and a deposition rate of 10˜200 Å/s.

In an exemplary embodiment of the present disclosure, the first molybdenum oxide substrate layer has a thickness not less than 50 Å.

According to a third aspect of the present disclosure, there is provided a display device comprising the above-mentioned array substrate.

It is to be understood that both the foregoing general description and the following detailed description are exemplary and explanatory only and are not restrictive of the invention, as claimed.

### BRIEF DESCRIPTION OF THE DRAWINGS

The accompanying drawings, which are incorporated in and constitute part of this specification, illustrate embodiments consistent with the invention and, together with the description, serve to explain the principles of the invention. The accompanying drawings, which are incorporated in and constitute a part of this specification, illustrate embodiments consistent with the invention and, together with the description, serve to explain the principles of the invention. Understandably, the drawings described below only illustrate some of embodiments of the present disclosure and those of ordinary skill in this art could obtain other drawings based on these drawings without any inventive work.

FIG. 1 shows a schematic structural diagram of an array substrate in an exemplary embodiment of the present disclosure;

FIG. 2 shows a comparison diagram of the reflectivity of various materials in the field;

FIG. 3 shows a schematic structural diagram of a thin film transistor whose gate electrode is formed by a metal wiring layer in an exemplary embodiment of the present disclosure;

FIG. 4 shows a schematic structural diagram of a thin film transistor with a source/drain electrode thereof being formed by a metal wiring layer in an exemplary embodiment of the present disclosure;

FIG. 5 shows a schematic structural diagram of a thin film transistor with a gate electrode and a source/drain electrode thereof being formed by two metal wiring layers in an exemplary embodiment of the present disclosure;

FIG. 6 is a flowchart showing the manufacturing of an array substrate in an exemplary embodiment of the present disclosure;

FIG. 7 is a flowchart showing the manufacturing of an array substrate in an exemplary embodiment of the present disclosure;

FIG. 8 is a flowchart showing the manufacturing of an array substrate in an exemplary embodiment of the present disclosure;

FIG. 9 is a flowchart showing the manufacturing of an array substrate in an exemplary embodiment of the present disclosure; and

FIG. 10 is a schematic structural diagram of a display device in an exemplary embodiment of the present disclosure.

### DETAILED DESCRIPTION

Example embodiments will now be fully described with reference to the accompanying drawings. However, the example embodiments can be carried out in various forms and should not be construed as being limited to examples set forth herein; rather, these embodiments are provided to make the present disclosure thorough and complete, and to fully convey the conception of the exemplary embodiments to those skilled in the art. Features, structures, or characteristics described herein may be combined in one or more embodiments in any appropriate way. In the description below, many specific details are provided for fully understanding embodiments of the present disclosure. However, it will be appreciated by those skilled in the art that the technical solution of the present disclosure can be practiced with one or more of the specific details being omitted, or other methods, components, devices, and steps may be used. Under other circumstances, a well-known technical solution will not be illustrated or described in detail to avoid obscuration of various aspects of the present disclosure.

In this specification, words such as “one,” “an/a,” “the,” and “said” are used indicate the presence of one or more elements, components, parts, and others. Terms “including” and “having” have an inclusive meaning which means that there may be additional elements, components, parts, and others in addition to the listed elements, components, parts, and others. Terms “first” and “second” are used herein only as markers, and they do not limit the number of objects modified after them.

In addition, the drawings are only schematic illustrations of the present disclosure and are not necessarily drawn to scale. The same reference numbers will be used throughout the drawings to refer to the same or like parts, and thus repeated descriptions thereof will be omitted. Some block diagrams in the drawings are functional entities and do not necessarily correspond to physically or logically independent entities.

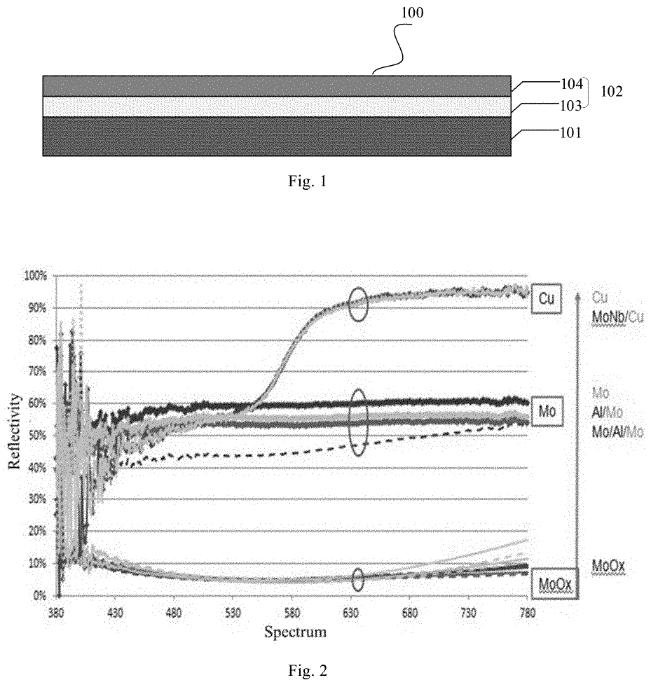

The present example embodiment provides an array substrate. As shown in FIG. 1, the array substrate 100 includes a base substrate 101 and a metal wiring layer 102. The metal wiring layer 102 is located on the base substrate 101, and includes a first molybdenum oxide substrate layer 103 and a first metal layer 104. The first metal layer 104 is located on a surface of the first molybdenum oxide substrate layer 103 away from the base substrate 101.

The base substrate 101 is a commonly-used base substrate in the art, such as a glass substrate or a quartz substrate. Optionally, the base substrate 101 is a glass substrate. The metal wiring layer 102 includes the first molybdenum oxide substrate layer 103 and the first metal layer 104. In order to improve electrical properties of the array substrate, the first metal layer 104 may be made of materials with high electric conductivity, such as copper, aluminum, or may be made of other metal materials or metal alloy materials with high electric conductivity that are commonly used in the art.

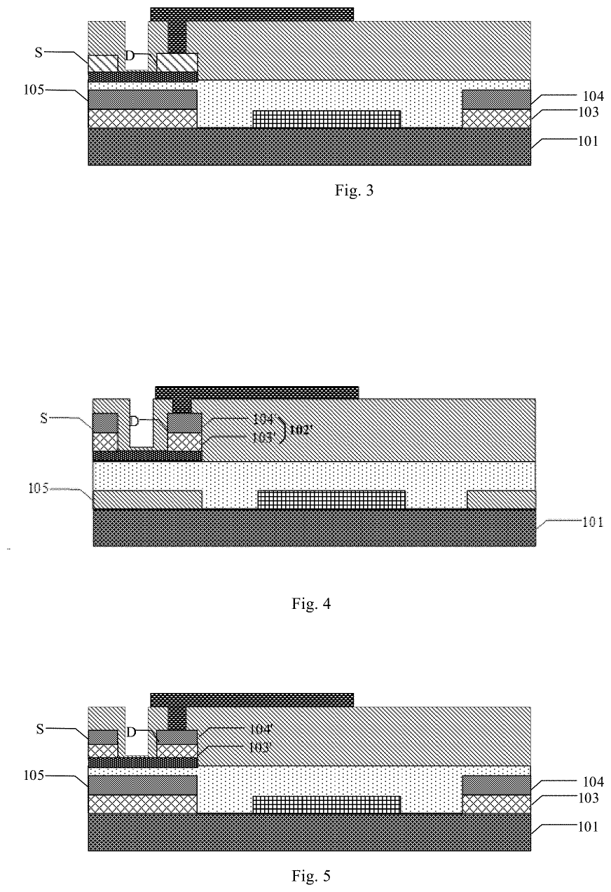

FIG. 2 shows reflectivity of various materials. As can be seen from FIG. 2, the reflectivity of Cu or MoNb/Cu is very high and the reflectivity of pure copper is about 95%. When molybdenum oxide is used as the substrate layer, incident light on a contact interface between a Cu metal trace and the molybdenum oxide is in the same phase as that of reflected light and light waves encounter in space to cause destructive interference, so the reflectivity of the Cu metal trace is greatly reduced by about 93%.

Compared with the direct adhering of the metal layer to the base substrate, the metal layer is sticked to the base substrate by using the molybdenum oxide substrate layer in the array substrate of the present disclosure. By doing this, on one hand, adhesion between the metal layer and the base substrate is enhanced. On the other hand, the reflectivity of the metal layer is reduced and metal elements in the metal layer are prevented from diffusing into the base substrate, thereby further improving the performance of the array substrate.

In an exemplary embodiment of the present disclosure, the first molybdenum oxide substrate layer has a thickness not less than 50 Å in order to increase adhesion between metal trace formed by the metal layer and the base substrate, and to minimize the reflectivity of the metal layer.

In an exemplary embodiment of the present disclosure, the array substrate 100 further includes a thin film transistor provided on the base substrate 101. The metal wiring layer 102 includes a gate electrode 105 of the thin film transistor. FIG. 3 shows a structural schematic diagram of a thin film transistor with its gate electrode 105 being formed by the metal wiring layer 102.

In another exemplary embodiment of the present disclosure, FIG. 4 shows a structural schematic diagram of a thin film transistor with a source/drain electrode thereof being formed by another metal wiring layer 102′. As shown in FIG. 4, the thin film transistor may further include a second molybdenum dioxide substrate layer 103′ and a second metal layer 104′. The source/drain (S/D) electrode of the thin film transistor is formed by patterning the second molybdenum oxide substrate layer 103′ and the second metal layer 104′.

In another exemplary embodiment of the present disclosure, FIG. 5 shows a structural schematic diagram of a thin film transistor with a gate electrode 105 and a source/drain (S/D) electrode thereof being formed by a metal wiring layer 102 and another metal wiring layer 102′, respectively. As shown in FIG. 5, the gate electrode 105 and the source/drain (S/D) electrode of the thin film transistor in the present disclosure may be obtained by patterning the two metal wiring layers, so as to further reduce the reflectivity of metal trace and improve the performance of a display device.

Furthermore, the metal wiring layer 102 may include a trace pattern on the array substrate 100. Any trace pattern formed on the base substrate 101 may be formed by patterning the metal wiring layer 102. The trace pattern may be a gate line pattern, a data line pattern or a signal line pattern, etc.

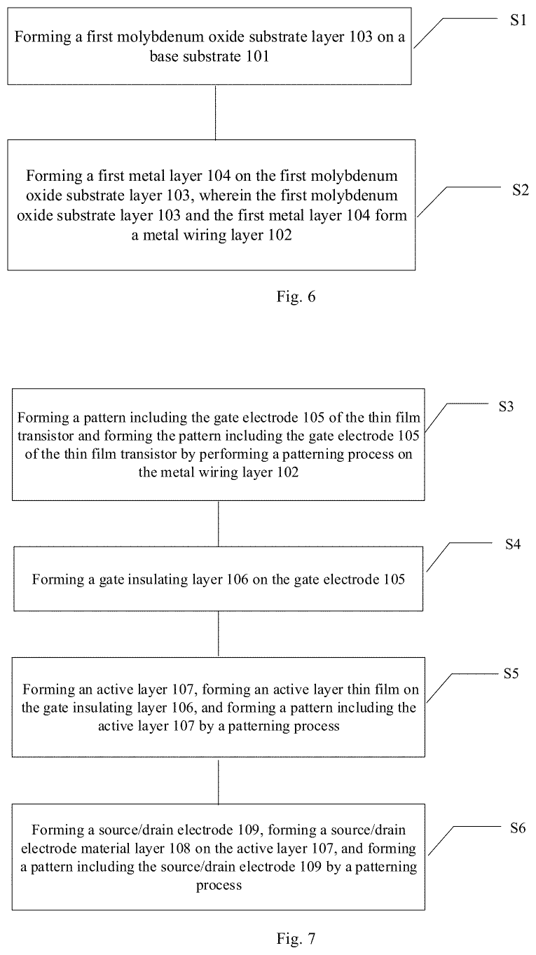

The present exemplary embodiment provides a method for manufacturing an array substrate. As shown in FIG. 6, the method specifically includes the following steps.

In S1, a first molybdenum oxide substrate layer 103 is formed on a base substrate 101.

The first molybdenum oxide substrate layer 103 is directly deposited and formed on the base substrate 101 by a PVD (physical vapor deposition) device. Specifically speaking, a molybdenum oxide metal block is used as a target material, which is then bombarded with inert gas ions, so that oxygen and molybdenum in the target material are bombarded out of the target material and deposited on the substrate to form a molybdenum oxide film. In order to ensure the uniformity of the molybdenum oxide film, the molybdenum oxide substrate layer 103 in the present disclosure has deposition parameters of an air pressure of 0.1·2 Pa, Ar flow rate of 10-3000 sccm, power of 0.5˜80 kw, a deposition rate of 10˜200 Å/s. Optionally, the gas pressure is 0.5-1 Pa, the Ar flow rate is 1350 sccm, the power is 11-13 kw and the deposition rate is 14 Å/s. Moreover, the first molybdenum oxide substrate layer has a thickness not less than 50 Å.

In S2, a first metal layer 104 is formed on the first molybdenum oxide substrate layer 103. The first molybdenum oxide substrate layer 103 and the first metal layer 104 form a metal wiring layer 102.

After the first molybdenum oxide substrate layer 103 is formed, the first metal layer 104 is formed on thereon. The first metal layer 104 may be made of materials with high electric conductivity such as copper, aluminum, or made of other metal materials or metal alloy materials with high electric conductivity that are commonly-used in the art. The first metal layer 104 may be formed by methods such as PVD, CVD, and/or PECVD. Optionally, the first metal layer 104 may be formed by adopting a PVD method. The first metal layer 104 and the first molybdenum oxide substrate layer 103 may be deposited and formed in order in the same device, reducing technological processes and improving the manufacturing efficiency.

In an exemplary embodiment of the present disclosure, a thin film transistor is formed on the metal wiring layer 102 after the metal wiring layer 102 is formed and a gate electrode 105 of the thin film transistor is formed by performing a patterning process on the metal wiring layer 102. Further, a source/drain (S/D) electrode of the thin film transistor may also be formed by carrying out a patterning process on another metal wiring layer. Specific processes are shown in FIG. 7.

In S3, a pattern including the gate electrode 105 of the thin film transistor is formed and the pattern including the gate electrode 105 of the thin film transistor is formed by performing a patterning process on the metal wiring layer 102.

An array substrate 100 includes a display area AA and a non-display area located around the display area AA. After the first molybdenum oxide substrate layer 103 and the first metal layer 104 are formed on the base substrate 101, the metal wiring layer 102 in an area D is removed by adopting a patterning process, so that the metal wiring layer 102 in the display area AA is formed as the gate electrode 105 of the thin film transistor and the metal wiring layer 102 in the non-display area is formed as a trace layer around the array substrate. The patterning process may be a photolithography process or other processes that are commonly used in the art. Optionally, the pattern including the gate electrode 105 is formed by adopting a photolithography process. Specifically speaking, a first mask layer is formed on the metal layer 104, and is exposed and developed to form patterns corresponding to areas where the gate electrode 105 and a trace of the non-display area are located. The metal wiring layer 102 in a non-gate electrode area and a non-trace area are exposed. The metal wiring layer 102 not covered by the first mask layer is then etched with an etching solution to form the gate electrode 105 and the trace. During etching, an etching time and an etching rate can be controlled by adjusting a concentration of the etching solution to avoid causing residue or over-etching to affect the performance of the array substrate.

In S4, a gate insulating layer 106 is formed on the gate electrode 105.

The gate insulating layer 106 is deposited on the gate electrode 105, the trace of the non-display area and the exposed base substrate 101 after the gate electrode 105 of the thin film transistor is formed. The gate insulating layer 106 may be made of SiOₓ, SiNₓ, or other insulating materials that are commonly used in the art, which is not particularly limited in the present disclosure.

In S5, an active layer 107 is formed, an active layer thin film is formed on the gate insulating layer 106, and a pattern including the active layer 107 is formed by a patterning process.

First, the active layer thin film is deposited on the gate insulating layer 106. The active layer thin film is made of a commonly-used material in the art, which will not be repeated here. The active layer thin film is then patterned by a patterning process to form the pattern including the active layer 107. The patterning process is similar to the patterning process for forming the gate electrode 105. The specific process is as follows: forming a second mask layer on the gate insulating layer 106, and exposing and developing the second mask layer to form a pattern corresponding to the active layer 107; and exposing a non-active layer area, and etching the non-active layer area with an etching solution to form the active layer 107. Etching time and an etching rate can be controlled by adjusting a concentration of the etching solution to avoid causing residue or over-etching.

In S6, a source/drain electrode 109 is formed, a source/drain electrode material layer 108 is formed on the active layer 107, and a pattern including the source/drain electrode 109 is formed by a patterning process.

A source/drain electrode material layer 108 is deposited on the active layer 107. The source/drain electrode material layer 108 may be metal materials or metal alloy materials with high electric conductivity that are commonly used in the art, such as Cu, Al, Au, and/or Ag. Alternatively, it may be a metal wiring layer in the present disclosure. Optionally, the source/drain electrode material layer is formed by using the metal wiring layer in the present disclosure. Namely, the source/drain electrode material layer 108 includes a second molybdenum oxide substrate layer and a second metal layer. The second molybdenum oxide substrate layer may further reduce the reflectivity of metal traces such as Cu and/or Al, thereby improving the performance of the array substrate 100 and the display device.

The patterning process for forming the source/drain electrode 109 is similar to the patterning process for forming the gate electrode 105. Specifically, a third mask layer may be formed on the source/drain electrode material layer 108, and may be exposed and developed to form the pattern corresponding to the source/drain electrode 109, a channel region is exposed and then the source/drain electrode material layer is etched with an etching solution to form the source/drain electrode 109 and a channel. Etching time and an etching rate can be controlled by adjusting a concentration of the etching solution to avoid causing residue or over-etching thus affecting the performance of the array substrate 100.

Further, a planarization insulating layer 110 is formed on the source/drain electrode 109 and the gate insulating layer 106 after the thin film transistor is formed by etching. Next, a fourth mask layer is formed on the planarization insulating layer 110 and is etched to form pixel via holes. The pixel via holes are then filled with a transparent conductive material and a fourth mask layer is formed on the transparent conductive material layer and is etched to form a pixel electrode 111. The transparent conductive material may be a transparent metal or a transparent metal oxide. Optionally, the transparent metal oxide, such as FTO, ZTO, ITO is employed.

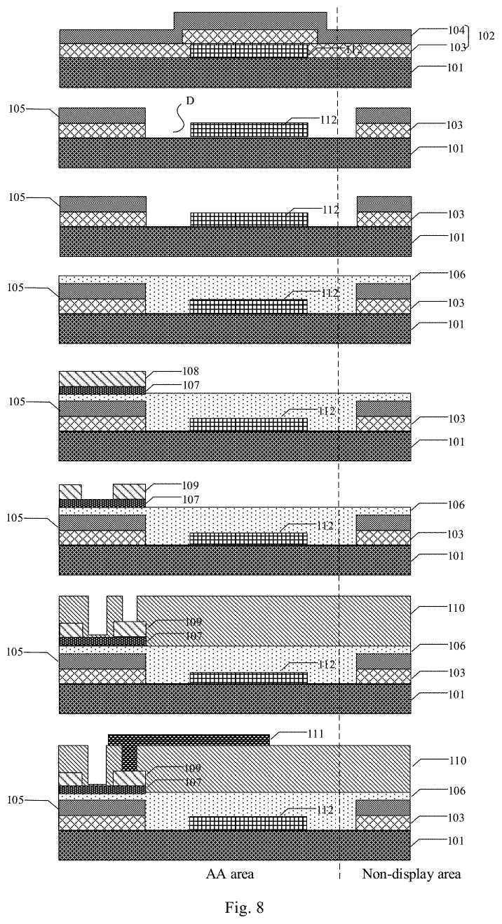

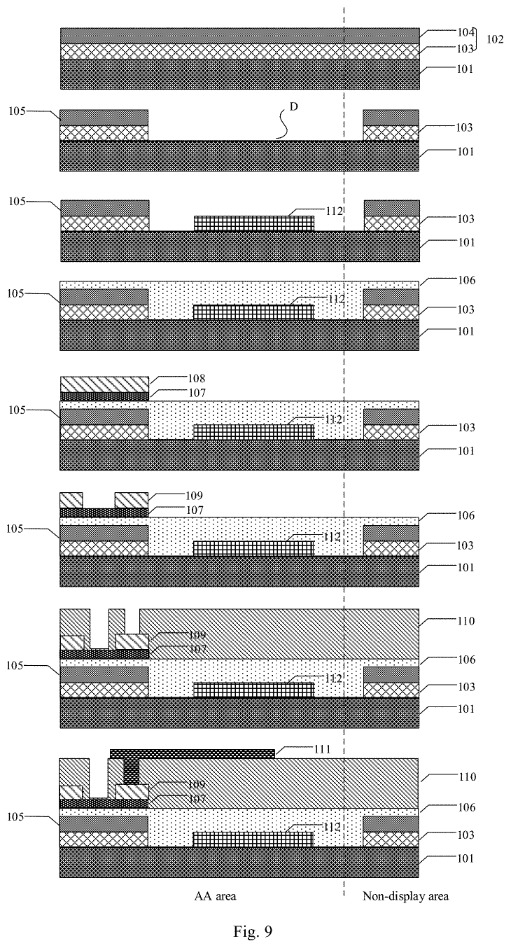

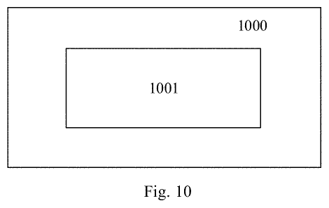

In the present exemplary embodiment, a transparent conductive layer may be deposited on the base substrate 101 in the display area AA before the metal wiring layer 102 is formed (see FIG. 8) or after the gate electrode 105 is formed (see FIG. 9). A common electrode 112 in a pixel area is formed by forming a mask layer on the transparent conductive layer and etching the transparent conductive layer.

In an exemplary embodiment of the present disclosure, the method for manufacturing the array substrate 100 further includes forming a trace pattern. The trace pattern is formed on the metal wiring layer by a patterning process. The trace pattern may be a gate line pattern, a data line pattern or a signal line pattern.

The present exemplary embodiment further provides a display device. As shown in FIG. 10, the display device 1000 includes a display panel 1001. The display panel 1001 is a display panel in the present disclosure. The display device 1000 may be products or components with a display function such as an electronic paper display, an OLED display, a mobile phone, a tablet computer, a television, a notebook computer, a digital photo frame, and a navigator.

Other embodiments of the invention will be apparent to those skilled in the art from consideration of the specification and practice of the invention disclosed here. This application is intended to cover any variations, uses, or adaptations of the invention following the general principles thereof and including such departures from the present disclosure as come within known or customary practice in the art. It is intended that the specification and examples be considered as exemplary only, with a true scope and spirit of the invention being indicated by the following claims.

It will be appreciated that the present invention is not limited to the exact construction that has been described above and illustrated in the accompanying drawings, and that various modifications and changes can be made without departing from the scope thereof. It is intended that the scope of the invention only be limited by the appended claims.

1. An array substrate, comprising:
a base substrate; and
a metal wiring layer located on the base substrate;
wherein the metal wiring layer comprises a first molybdenum oxide substrate layer and a first metal layer on a surface of the first molybdenum oxide substrate layer away from the base substrate.

2. The array substrate according to claim 1, wherein the first molybdenum oxide substrate layer is a substrate layer directly formed through a physical vapor deposition method.

3. The array substrate according to claim 1, wherein the array substrate further comprises a thin film transistor provided on the base substrate, and a gate electrode of the thin film transistor comprises the metal wiring

4. The array substrate according to claim 3, wherein a source/drain electrode of the thin film transistor comprises a second molybdenum oxide substrate layer and a second metal layer on a surface of the second molybdenum oxide substrate layer away from the base substrate.

5. The array substrate according to claim 1, wherein the array substrate further comprises a trace pattern, and the trace pattern comprises the metal wiring layer.

6. The array substrate according to claim 1, wherein the first molybdenum oxide substrate layer has a thickness not less than 50 Å.

7. The array substrate according to claim 1, wherein the first metal layer is made of copper or aluminum.

8. The array substrate according to claim 1, wherein the base substrate comprises a glass substrate.

9. A method for manufacturing an array substrate, comprising:
forming a first molybdenum oxide substrate layer on a base substrate; and
forming a first metal layer on a surface of the first molybdenum oxide substrate layer away from the base substrate;
wherein the first molybdenum oxide substrate layer and the first metal layer form a metal wiring layer.

10. (canceled)

11. The method for manufacturing the array substrate according to claim 9, further comprising forming a thin film transistor on the base substrate, wherein forming the thin film transistor on the base substrate comprises:
forming the pattern comprising the gate electrode of the thin film transistor through a patterning process performed on the metal wiring layer;
forming the gate insulating layer on the gate electrode;
forming an active layer thin film on the gate insulating layer, and forming a pattern comprising the active layer through a patterning process; and
forming a source/drain electrode material layer on the active layer, and forming a pattern comprising the source/drain electrode through a patterning process.

12. The method for manufacturing the array substrate according to claim 11, wherein forming the source/drain electrode comprises:
forming a second molybdenum oxide substrate layer on the active layer;
forming a second metal layer on the second molybdenum oxide base layer; and
forming the pattern comprising the source/drain electrode through a patterning process.

13. The method for manufacturing the array substrate according to claim 9, further comprising forming a trace pattern on the metal wiring layer through a patterning process.

14. The method for manufacturing the array substrate according to claim 9, wherein the first molybdenum oxide substrate layer is directly formed through a physical vapor deposition method with deposition parameters of argon flow rate of 10˜3000 sccm, an air pressure of 0.1-2 Pa, power of 0.5-80 kw, and a deposition rate of 10˜200 Å/s.

15. The method for manufacturing the array substrate according to claim 14, wherein the first molybdenum oxide substrate layer has a thickness not less than 50 Å.

16. A display device, comprising:
an array substrate, comprising:
a base substrate; and
a metal wiring layer located on the base substrate;
wherein the metal wiring layer comprises a first molybdenum oxide substrate layer and a first metal layer on a surface of the first molybdenum oxide substrate layer away from the base substrate.

17. The array substrate according to claim 2, wherein:
the array substrate further comprises a thin film transistor provided on the base substrate;
the metal wiring layer comprises a gate electrode of the thin film transistor; and
a gate electrode of the thin film transistor comprises the metal wiring layer.

18. The array substrate according to claim 2, wherein the array substrate further comprises a trace pattern, and the trace pattern comprises the metal wiring layer.

19. The array substrate according to claim 3, wherein the array substrate further comprises a trace pattern and the trace pattern comprises the metal wiring layer.

20. The array substrate according to claim 2, wherein the first molybdenum oxide substrate layer has a thickness not less than 50 Å.

21. The array substrate according to claim 2, wherein the first metal layer is made of copper or aluminum.
